(19) United States
(12) Patent Application Publication
(10) Pub. No.: US 2014/0224177 A1
(43) Pub. Date: Aug. 14, 2014

(54) INJECTION MEMBER IN FABRICATION OF SEMICONDUCTOR DEVICE AND SUBSTRATE PROCESSING APPARATUS HAVING THE SAME

(71) Applicants: Yong Sung Park, Chungcheongnam-do (KR); Sung Kwang Lee, Chungcheongnam-do (KR); Dong Yeul Kim, Chungcheongnam-do (KR); Hong Joo Bang, Chungcheongnam-do (KR); Min Seok Kim, Chungcheongnam-do (KR)

(72) Inventors: Yong Sung Park, Chungcheongnam-do (KR); Sung Kwang Lee, Chungcheongnam-do (KR); Dong Yeul Kim, Chungcheongnam-do (KR); Hong Joo Bang, Chungcheongnam-do (KR); Min Seok Kim, Chungcheongnam-do (KR)

(73) Assignee: KOOKJE ELECTRIC KOREA CO., LTD., Chungcheongnam-do (KR)

(21) Appl. No.: 14/126,656

(22) PCT Filed: May 30, 2012
(86) PCT No.: PCT/KR2012/004267

§ 371 Date: Apr. 21, 2014

(30) Foreign Application Priority Data
Jun. 24, 2011 (KR) 10-2011-0061897

(51) Int. Cl. H01L 21/02; B05B 1/00

(52) U.S. Cl. CPC H01L 21/02104; B05B 1/005
USPC 118/730; 239/520

(57) ABSTRACT

Provided is a substrate processing apparatus which include a process chamber in which a plurality of substrates are accommodated to be processed, a support member mounted at the process chamber and having the same plane on which a plurality of substrate are placed, an injection member mounted opposite to the support member and including a plurality of independent baffles to independently inject the least one reactive gas and the purge gas at positions respectively corresponding to the plurality of substrates placed on the support member, and a driving unit adapted to rotate the support member or the injection member such that the baffles of the injection member sequentially revolve around the plurality of respective substrates. The injection member includes a plasma generator mounted at least one of the baffles to plasmatize a reactive gas injected to a substrate.

### CROSS-REFERENCE TO RELATED APPLICATIONS

This U.S. non-provisional patent application claims priority under 35 U.S.C. §119 of Korean Patent Application No. 10-2011-0061897, filed on Jun. 24, 2011, the entire contents of which are hereby incorporated by reference.

### FIELD

The present general inventive concept relates to thin film processing apparatuses for use in fabrication of semiconductor devices and, more particularly, to an injection member with improved gas flow and a substrate processing apparatus including the same.

### BACKGROUND

Apparatuses using plasma have been widely used in unit processes such as dry etch, physical or chemical vapor deposition (PVD or CVD), and other surface treatments.

Existing substrate processing apparatuses include a semi-batch type substrate processing apparatus capable of processing a plurality of substrates on the same plane. A semi-batch type substrate processing apparatus includes a nozzle for gas injection. The nozzle for gas injection is disposed in the center of the semi-batch type substrate processing apparatus to inject a gas toward the edge of the semi-batch type substrate processing apparatus. For this reason, there are significant differences in gas jetting speed and density on a substrate. In addition, a vortex is generated to deteriorate the quality of a thin film.

### SUMMARY

An aspect of the inventive concept is directed to an injection member for use in a substrate processing apparatus. In some embodiments, the injection member may include a disk-shaped top plate; four baffles demarcated by partitions radially mounted on a bottom surface of the top plate; and side nozzle unit mounted at the partitions in a length direction to inject a gas to each of the at least four baffles.

In an example embodiment, the side nozzle unit may be a rod-shaped injector having an internal path and nozzles through which a gas flowing along the internal path is injected.

In an example embodiment, the nozzles may be larger in size as they come close to the edge from the center of the top plate.

In an example embodiment, the nozzles may have a horizontal injection angle to inject gas a direction horizontal to a target surface of a substrate.

In an example embodiment, the nozzles may have a downwardly inclined injection angle to obliquely inject a gas to a target surface of a substrate.

In an example embodiment, the injection member may further include a central nozzle unit mounted in the center of the top plate and having at least four nozzles for independently injecting externally supplied at least one reactive gas and a purge gas to the four baffles.

In an example embodiment, the side nozzle units may receive a gas through the central nozzle unit.

Another aspect of the inventive concept is directed to a substrate processing apparatus. In some embodiments, the substrate processing apparatus may include a process chamber in which a plurality of substrates are accommodated to be processed; a support member mounted at the process chamber and having the same plane on which a plurality of substrate are placed; an injection member mounted opposite to the support member and including a plurality of independent baffles to independently inject the least one reactive gas and the purge gas at positions respectively corresponding to the plurality of substrates placed on the support member; and a driving unit adapted to rotate the support member or the injection member such that the baffles of the injection member sequentially revolve around the plurality of respective substrates. The injection member includes a top plate; partitions mounted on a bottom surface of the top plate to demarcate the plurality of baffles; and a side nozzle unit mounted at the partitions and adapted to inject at least one reactive gas and a purge gas to the corresponding baffles.

In an example embodiment, the injection member may further include a central nozzle unit mounted in the center of the top plate and adapted to inject externally supplied at least one reactive gas and a purge gas to the corresponding baffles.

### BRIEF DESCRIPTION OF THE DRAWINGS

The inventive concept will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the inventive concept.

FIG. 1 illustrates an atomic layer deposition (ALD) apparatus according to the inventive concept.

FIGS. 2A and 2B are a perspective view and a cross-sectional view of an injection member in FIG. 1, respectively.

FIG. 3 is a top plan view of the injection member in FIG. 1.

FIG. 4 is a cross-sectional view taken along the line A-A in FIG. 2B.

FIG. 5A is an enlarged cross-sectional view of a main portion of an injection member, which illustrates a plasma generator.

FIG. 5B shows a state where the plasma generator in FIG. 5A is lowered by a height adjuster.

FIG. 6 illustrates a modified embodiment of an injection member.

FIG. 7 is a cross-sectional view a side injection unit, which illustrates a nozzle with various injection angles.

### DETAILED DESCRIPTION OF THE EMBODIMENTS

The inventive concept will now be described more fully hereinafter with reference to the accompanying drawings, in which preferred embodiments of the inventive concept are shown. However, the inventive concept may be embodied in many different forms and should not be construed as limited to the embodiments set forth herein. Rather, these embodiments are provided so that this disclosure will be thorough and complete, and will fully convey the scope of the inventive concept to those skilled in the art. Like numbers refer to like elements throughout.

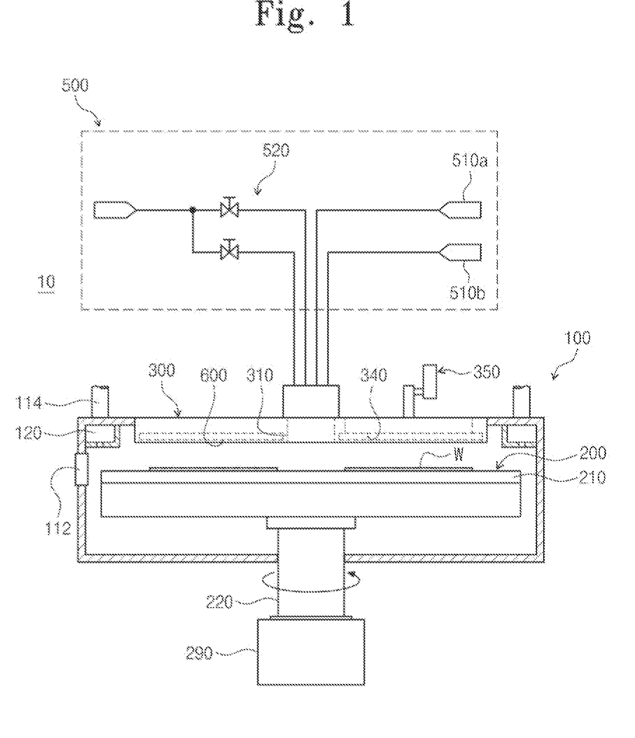

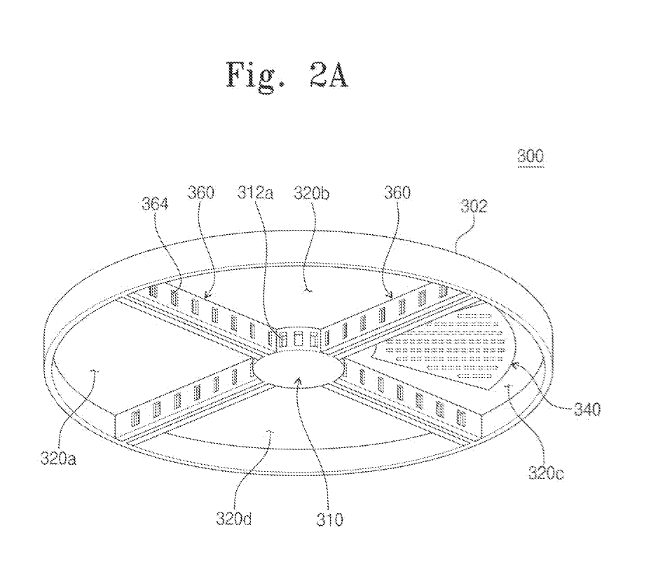

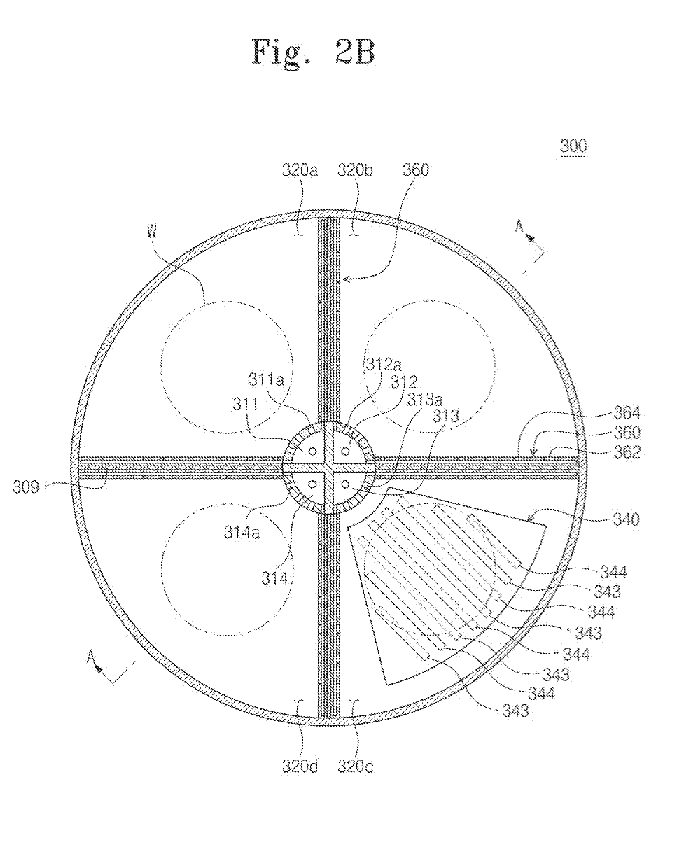

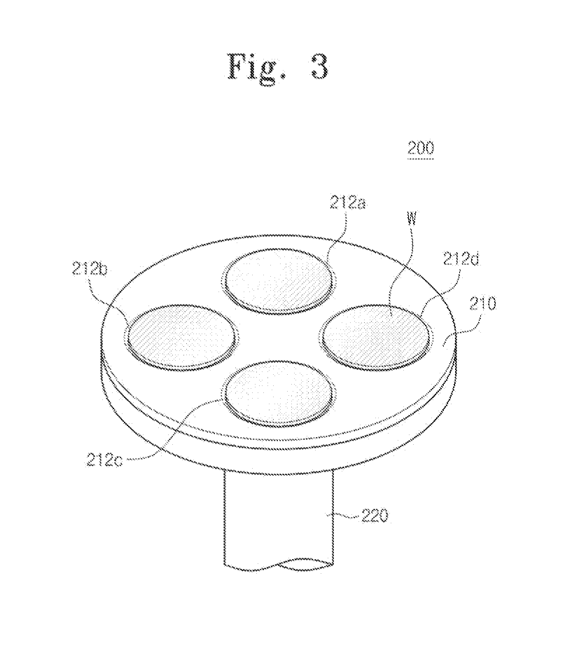

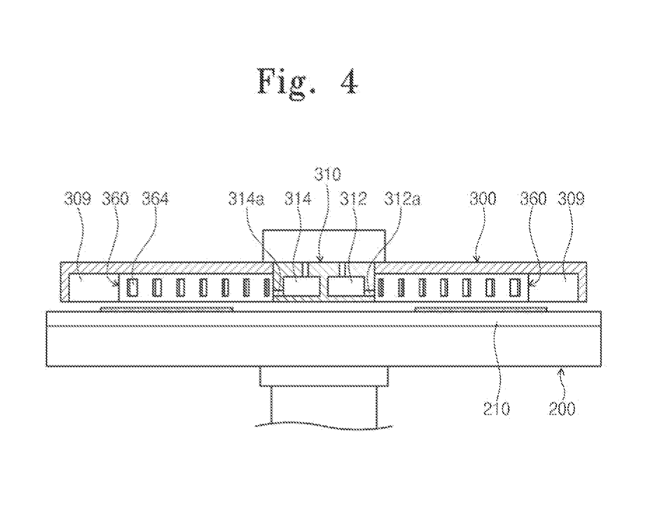

FIG. 1 illustrates an atomic layer deposition (ALD) apparatus according to the inventive concept. FIGS. 2A and 2B are a perspective view and a cross-sectional view of an injection member in FIG. 1, respectively. FIG. 3 is a top plan view of the injection member in FIG. 1. FIG. 4 is a cross-sectional view taken along the line A-A in FIG. 2B.

Referring to FIGS. 1 to 4, an ALD apparatus 10 according to an embodiment of the inventive concept includes a process chamber 100, a support member 200, an injection member 300, and a supply member 500.

An entrance 112 is provided at one side of the process chamber 100. During a process, substrates W enter or exit through the entrance 112. The process chamber 100 includes an exhaust duct 120 and an exhaust pipe 114 disposed at its upper edge for exhausting a reactive gas and a purge gas supplied into the process chamber 110 and reactive byproducts produced during an ALD process. The exhaust duct 120 is provided in the form of a ring disposed outside the injection member 300. Although not shown, it is apparent to those skilled in the art that the exhaust pipe 114 is connected to a vacuum pump and a pressure control valve, a flow control valve, and the like are mounted on the exhaust pipe 114.

As shown in FIGS. 1 and 3, the support member 200 is mounted in an internal space of the process chamber 100.

The support member 200 is a batch-type member on which four substrates are placed. The support member 200 includes a disk-shaped table 210 with four stages having top surfaces on which substrates are placed and a support column 220 supporting the table 210. The first to fourth stages 212a-212d may have a similar cylindrical shape to a substrate. The first to fourth stages 212a-212d are arranged at right angles on a concentric circle, on the basis of the center of the support member 200.

The support member 200 is rotated by a driving unit 290. Preferably, the driving unit 290 rotating the support member 200 employs a stepping motor in which an encoder is mounted to control the revolution number and speed of a driving motor. The encoder controls a first cycle process (first reactive gas-purge gas-second reactive gas-purges gas)time of the injection member 300.

Although not shown, the support member 200 may be provided with a plurality of lift pins (not shown) elevating and decending substrates from the respective stages. The lift pin elevates a substrate W and thus allows the substrate W to be spaced apart from the stage of the support member 200 or to be loaded on the stage. In addition, a heater (not shown) may be provided at the respective stages 212a-212d to heat loaded substrates W. The heater heats a substrate W to increase a temperature of the substrate W to a predetermined temperature (process temperature).

Referring to FIGS. 1 and 2B, the supply member 500 includes a first gas supply member 510a, a second gas supply member 510b, and a purge gas supply member 520. The first gas supply member 510a supplies a first reactive gas for forming a predetermined thin film on a substrate W into a first chamber 320a of a nozzle unit. The second gas supply member 510b supplies a second reactive gas into a third chamber 320c. The purge gas supply member 520 supplies a purge gas into second and fourth chambers 320b and 320d. For example, the first reactive gas and the second reactive gas are gases containing raw materials constituting a thin film desired to be formed on a substrate W. Particularly, in an atomic layer deposition (ALD) process, a plurality of different reactive gases are provided and chemically react on a substrate surface to form a predetermined thin film on the substrate. Also in the ALD process, a purge gas is supplied between supplying one reactive gas and supplying another reactive gas to purge non-reactive gases remaining on the substrate W.

In this embodiment, two gas supply members are used to supply two different reactive gases. However, it will be understood that a plurality of gas supply members are provided to supply three or more different reactive gases based on process characteristics.

Referring to FIGS. 1, 2A, 2B, and 4, the injection member 300 injects a gas onto four respective substrates placed on the support member 200.

The injection member 300 receives the first and second reactive gases and the purge gas from the supply member 500. The injection member 300 includes a disk-shaped top plate 302, a central nozzle 310, side nozzle units 360, first to fourth baffles 320a-320d, a plasma generator 340, and a height adjuster 350.

The central nozzle unit 310 is mounted on a central portion of the top plate 302. The central nozzle unit 310 independently injects the first and second reactive gases and the purges gas supplied from the supply member 500 to the first to fourth baffles 320a-320d. The central nozzle unit 310 includes first to fourth chambers 311, 312, 313, and 314. The first reactive gas is supplied into the first chamber 311, and nozzles 311a are formed at a side surface of the first chamber 311 to supply the first reactive gas to the first baffle 320a. The second reactive gas is supplied into the third chamber 313, and nozzles 313a are formed at a side surface of the third chamber 313 to supply the second reactive gas to the third baffle 320c. The purge gas is supplied into the second and fourth chambers 312 and 314 disposed between the first and third chambers 311 and 313, and nozzles 312a and 314a are formed at side surfaces of the second and fourth chambers 312 and 314 to supply the purge gas to the second and fourth baffles 320b and 320d, respectively. Nozzles 311a of the central nozzle unit 310 may be various types of nozzles such as a horizontally slim nozzle or a porous nozzle. The nozzles 311a of the central nozzle unit 310 may constitute a single-layer structure or a multi-layer structure. In addition, the nozzles 311a of the central nozzle unit 310 may have inclined injection angles to radially inject gases.

The side nozzle units 360 are mounted at partitions demarcating the first to fourth baffles 320a-320d, respectively. The side nozzle units 360 are arranged in a V shape around the central nozzle unit 310 such that two side nozzle units 360 form a pair at one baffle. The injection member 300 including four baffles is provided with total eight side nozzle units 360. The side nozzle unit 360 improves a flow (density and speed) of a gas provided to a target surface of a substrate W to enhance the quality of a thin film. Two side nozzle units 360 mounted at one baffle are symmetrically arranged around the center (baffle space) of the substrate W.

The side nozzle unit 360 has a rod shape and includes an internal path 362 and a plurality of nozzles 364 at its one surface. The side nozzle units 360 receive gases through the respective chambers 311, 312, 313, and 314 of the central nozzle unit 310. For achieving this, the internal path 362 of the side nozzle unit 360 communicates with the respective chambers 311, 312, 313, and 314 of the central nozzle unit 310. The nozzles 364 of the side nozzle unit 360 may vary in size depending on their locations. As shown in FIGS. 2A and 4, the nozzles 364 are smaller in size as they come close to the central nozzle unit 310 while being larger in size as they go far away from the central nozzle unit 310. This is because in a central region near the central nozzle unit 310, sufficient gas supply and density may be maintained even with less amount of gas due to short distance between the side nozzle units 360. Also this is because in an edge region relatively far away from the central nozzle unit 310, much amount of gas is injected for sufficient gas supply (density maintenance) due to long distance between the side nozzle units 360.

The nozzles 364 of the side nozzle unit 360 may have an injection angle horizontal to a substrate. However, if necessary, the nozzles 364 of the side nozzle unit 360 may have an injection angle inclined toward the substrate.

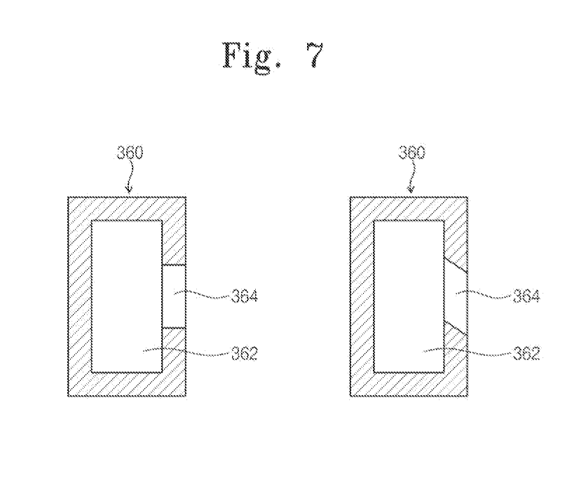

FIG. 7 shows a side nozzle unit 360 including a nozzle 364 with a horizontal injection angle to inject a gas in a direction horizontal to a target surface of a substrate and a side nozzle unit 360 including a nozzle 364 with a downwardly inclined injection angle to obliquely inject a gas to the target surface of a substrate.

The side nozzle unit 360 may directly receive a gas through a separate supply line, not through the central nozzle unit 310. In this case, a supply line (position where a gas is introduced to a side nozzle unit) is preferably connected to a central portion of the side nozzle unit 360. When the side nozzle unit 360 directly receives a gas through a supply line, the nozzles 364 are small in size as they are close to a gas supply point while being large in size as they are far away from the gas supply point.

As described above, the injection member 300 allows a gas to be uniformly injected to the entire target surface of a substrate by injecting the gas through the central nozzle unit 310 and a pair of side nozzles 360 in three directions. In addition, since the gas is injected toward the substrate in the three directions, generation of a vortex may be minimized to enhance the quality of a thin film during formation of the thin film.

The first to fourth baffles 320a-320d have independent spaces for supplying the gases received from the central nozzle unit 310 and the side nozzle units 360 to the entire target surface of the substrate at positions respectively corresponding to substrates. The first to fourth baffles 320a-320d are demarcated by partitions 309 mounted on a bottom surface of the top plate 302.

The first to fourth baffles 320a-320d are radially arranged below the top plate 302 in the shape of fans divided at right angles around the central nozzle unit 310. The first to fourth baffles 320a-320d communicate with nozzles 311a, 312a, 313a, and 314a of the central nozzle unit 310 and nozzles of the side nozzle unit 360, respectively. The first to fourth baffles 320a-320d are formed with open bottom surfaces facing the support member 200.

The gases supplied from the central nozzle unit 310 and the pair of side nozzle units 360 are supplied to the independent spaces of the first and fourth baffles, respectively. The gases supplied to the independent spaces are naturally supplied to the substrate through the open bottom surfaces. A first reactive gas is supplied to the first baffle 320a, and a second reactive gas is supplied to the third baffle 320c. A purge gas is supplied to the second and fourth baffles 320b and 320d disposed between the first and third baffles 320a and 320c to prevent mixture of the first and second reactive gases and purse non-reactive gases.

For example, while the first to fourth baffles 320a-320d of the injection member 300 are arranged in the shape of fans at right angles, the inventive concept is not limited thereto and they may be formed at regular intervals of 45 or 180 degrees and vary in size according to process purposes or characteristics.

According to the inventive concept, substrates sequentially pass below the first to fourth baffles 320a-320d as the support member 200 is rotated. When all the substrate pass the first to fourth baffles 320a-320d, a pair of atomic layers are deposited on a substrate W. Likewise, continuous rotation of a substrate allows a thin film having a predetermined thickness to be deposited on the substrate.

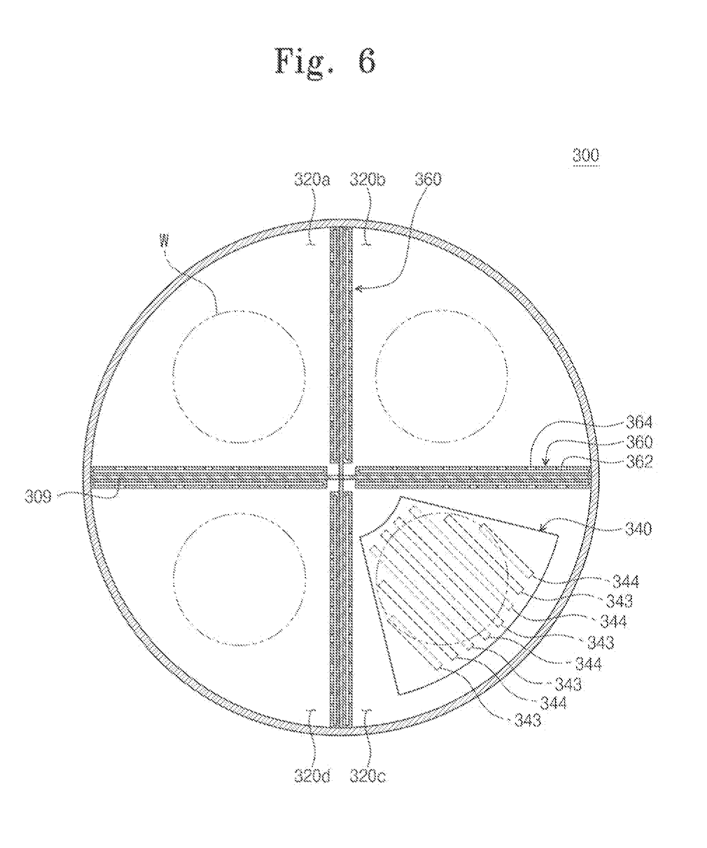

FIG. 6 shows an injection member 300 without a central nozzle unit.

As shown in FIG. 6, since the injection member 300 has no central injection, gas supply to side nozzle units 360 is conducted through a separate supply line (not shown). Side nozzle units 360 of the injection member 300, where gas supply is conducted through a separate supply line, may vary in height according to process characteristics.

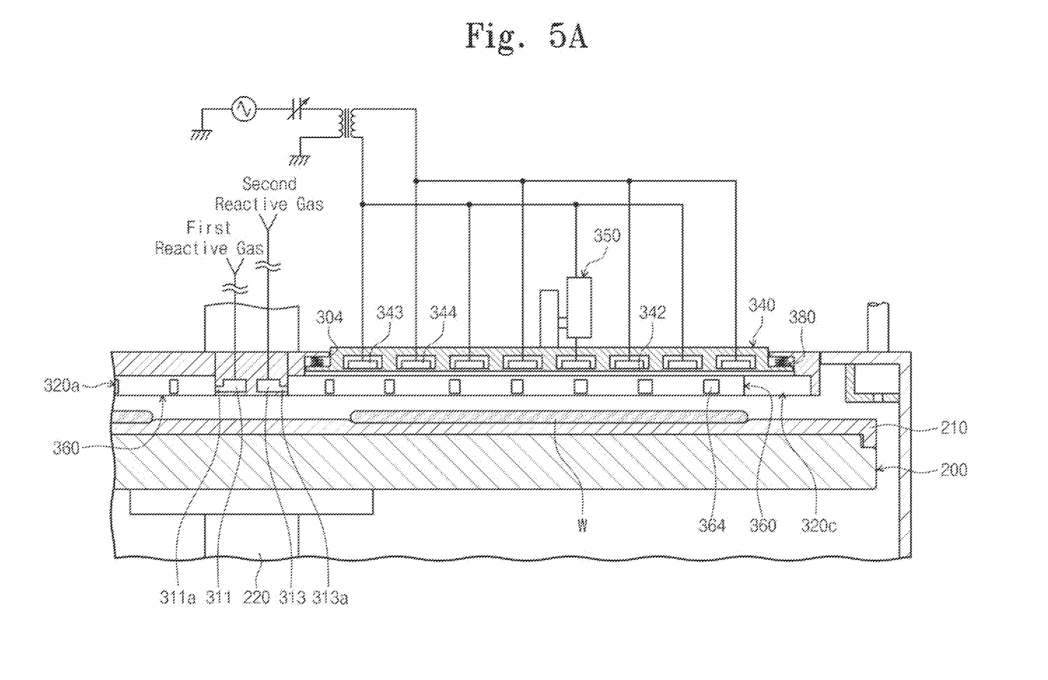

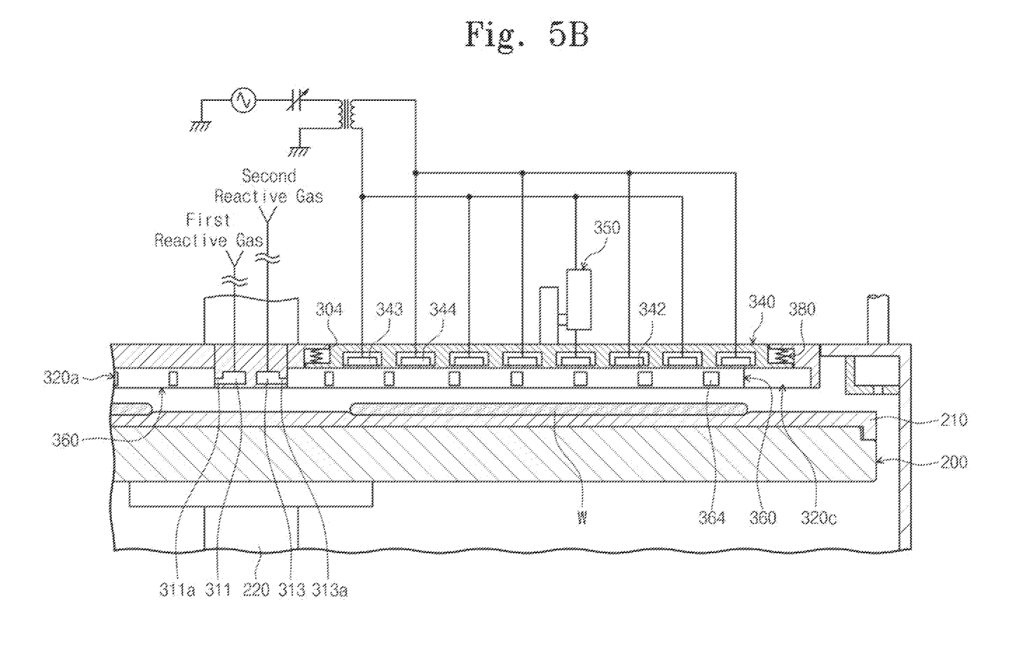

FIG. 5A is an enlarged cross-sectional view of a main portion of an injection member 300, which illustrates a plasma generator 340. FIG. 5B shows a state where the plasma generator 340 in FIG. 5A is lowered by a height adjuster.

The plasma generator 340 may be vertically movably mounted on at least one baffle of the injection member 300. In this embodiment, it will be described that the plasma generator 340 is vertically movably mounted on a third baffle 300c. However, it will be understood that if necessary, the plasma generator 340 may be mounted on another baffle.

Referring to FIGS. 2A, 2B, 5A and 5B, the plasma generator 340 is mounted at an opening 304 formed at a top plate 302 corresponding to a section of the third baffle 320c. The plasma generator 340 is vertically movably mounted independently of the third baffle 320c. The plasma generator 340 is surrounded by bellows 380 to maintain airtightness. Although not shown, in the case that the injection member 300 is mounted in an internal space of a process chamber, the plasma generator 340 may be configured to be connected to a separate elevation shaft mounted to penetrate an upper cover of a process chamber and an elevation shaft disposed outside the chamber may be configured to be elevated by a height adjuster. In this case, a bellows is mounted to cover the elevation shaft penetrating the upper cover of the process chamber. In this embodiment, since a top plate of an injection member is adapted as a part of the upper cover of the process chamber, the bellows 380 is mounted on the opening 304 to cover the plasma generator 340.

The plasma generator 340 is mounted on the third baffle 320c and plasmatizes a second reactive gas to improve reactivity of the second reactive gas and increases density of plasma in the third baffle 320c to enhance deposition rate and quality of a thin film.

The plasma generator 340 includes first electrodes 343 to which a radio frequency (RF) power is applied for generating a gas in form of plasma and second electrodes 344, disposed between the first electrodes 343, to which a bias power is applied. The first electrodes 343 and the second electrodes 344 are disposed on the same plane at the inside of a bottom surface 342 of the body 341 of the plasma generator 340. The first and second electrodes 343 and 344 are arranged in form of rods at regular intervals to intersect each other. The first and second electrodes 343 and 344 are arranged in a direction perpendicular to their rotation direction (arranged in form of comb or radially in a direction toward the center of rotation). In this case, another RF power may be applied to the second electrodes 344.

The bottom surface 342 of the body of the plasma generator 340 is formed to face the support member 200. The body 341 of the plasma generator 340 may be made of a quartz or ceramic material with insulating, heat-resistant, and chemical-resistant properties to prevent an effect caused by the first electrodes 343 and the second electrodes 344 from being imposed on the inside of a process chamber.

In the inventive concept, a substrate W is surface-treated with a plasmatized second reactive gas while passing below the third baffle 320 on which the plasma generator 340 is mounted. That is, when an RF power and a bias power are applied to the first and second electrodes 343 and 344 of the plasma generator 340 and the second reactive gas is supplied to the third baffle 320c through a pair of side nozzle units 360, the second reactive gas is supplied onto a substrate after being excited to a plasma state by an inducted magnetic field generated at the plasma generator 340 mounted on the third baffle 320c.

A height adjuster 350 is mounted outside a process chamber and elevates the plasma generator 340 to adjust a distance between the plasma generator 340 and a substrate.

That is, the height adjuster 350 for elevation of the plasma generator 340 is provided such that a distance between a substrate and a plasma generation area (third baffle space) may be adjusted according to the state of a substrate, a gas used, and a use environment to form a thin film.

An elevation height of the plasma generator 340 is within the range of preventing nozzles of a side nozzle unit from being blocked.

In an atomic layer deposition (ALD) apparatus according to the inventive concept, a plasma generator is mounted on an injection member in the form of semi-remote plasma. While a distance between the plasma generator and a substrate is kept at the range from several millimeters to tens of millimeters rather than a typical remote plasma generator, a reactive gas is radicalized through direct decomposition of a reactive gas to form a thin film. Particularly, a plasma generator according to the inventive concept generates plasma by simultaneously disposing a first electrode and a second electrode and thus it is not necessary to mount an additional equipment on a chamber, a body, and the like.

In case of a typical single equipment, a distance between a plasma generation region and a substrate is adjusted by elevating and descending a susceptor. However, in the inventive concept, only a plasma generator adopts a separate independent elevation structure and thus a distance between the plasma generator and a substrate may be adjusted according to the state of the substrate, a gas used, and an environment to form a thin film.

The inventive concept may be applied to an apparatus in which at least two gases are sequentially injected onto a substrate to process a surface of the substrate.

As a preferred embodiment, a batch-type atomic layer deposition (ALD) apparatus for use in an ALD process has been described. Also the inventive concept may be applied to a thin film deposition apparatus using high-density plasma (HDP) as well as deposition and etching apparatuses using plasma.

As described so far, gases are injected in three directions through a central nozzle unit and side nozzle units. Thus, uniform gas density is provided on a baffle to enhance deposition rate and quality of a thin film.

While the inventive concept has been particularly shown and described with reference to exemplary embodiments thereof, it will be apparent to those of ordinary skill in the art that various changes in form and detail may be made therein without departing from the spirit and scope of the inventive concept as defined by the following claims.

1. An injection member for use in a substrate processing apparatus, comprising:
a disk-shaped top plate;
at least four baffles demarcated by partitions radially mounted on a bottom surface of the top plate; and
side nozzle unit mounted at the partitions in a length direction to inject a gas to each of the at least four baffles.

2. The injection member as set forth in claim 1, wherein the side nozzle unit is a rod-shaped injector having an internal path and nozzles through which a gas flowing along the internal path is injected.

3. The injection member as set forth in claim 2, wherein the nozzles are larger in size as they come close to the edge from the center of the top plate.

4. The injection member as set forth in claim 2, wherein the nozzles have a horizontal injection angle to inject gas a direction horizontal to a target surface of a substrate.

5. The injection member as set forth in claim 2, wherein the nozzles have a downwardly inclined injection angle to obliquely inject a gas to a target surface of a substrate.

6. The injection member as set forth in claim 1, further comprising:
a central nozzle unit mounted in the center of the top plate and having at least four nozzles for independently injecting externally supplied at least one reactive gas and a purge gas to the four baffles.

7. The injection member as set forth in claim 6, wherein the side nozzle units receive a gas through the central nozzle unit.

8. A substrate processing apparatus comprising:
a process chamber in which a plurality of substrates are accommodated to be processed;
a support member mounted at the process chamber and having the same plane on which a plurality of substrate are placed;
an injection member mounted opposite to the support member and including a plurality of independent baffles to independently inject the least one reactive gas and the purge gas at positions respectively corresponding to the plurality of substrates placed on the support member; and
a driving unit adapted to rotate the support member or the injection member such that the baffles of the injection member sequentially revolve around the plurality of respective substrates,
wherein the injection member comprises:
a top plate;
partitions mounted on a bottom surface of the top plate to demarcate the plurality of baffles; and
a side nozzle unit mounted at the partitions and adapted to inject at least one reactive gas and a purge gas to the corresponding baffles.

9. The substrate processing apparatus as set forth in claim 8, wherein the injection member further comprises:
a central nozzle unit mounted in the center of the top plate and adapted to inject externally supplied at least one reactive gas and a purge gas to the corresponding baffles.
